(19) United States
(12) Patent Application Publication
(10) Pub. No.: US 2025/0017058 A1
(43) Pub. Date: Jan. 9, 2025

(54) DISPLAY DEVICE

(71) Applicant: Samsung Display Co., LTD., Yongin-si (KR)

(72) Inventors: Young Kwan KIM, Yongin-si (KR); Dong Jin KIM, Yongin-si (KR)

(73) Assignee: Samsung Display Co., LTD., Yongin-si (KR)

(21) Appl. No.: 18/442,578

(22) Filed: Feb. 15, 2024

(30) Foreign Application Priority Data
Jul. 6, 2023 (KR) 10-2023-0087715

(51) Int. Cl. H10K 59/126; H10K 59/127; H10K 59/40; H10K 59/80; H10K 102/00

(52) U.S. Cl. CPC H10K 59/126; H10K 59/127; H10K 59/40; H10K 59/873; H10K 2102/3026

(57) ABSTRACT

A display device includes a light emitting element layer on a substrate, a light control layer on the light emitting element layer, the light control layer including a light-transmitting film and a light-shielding film, and a first alignment mark between the substrate and the light control layer, the light-transmitting film and the light-shielding film alternate with each other, the light control layer includes a light-shielding film removal area in which the light-shielding film is not disposed, and the light-shielding film removal area overlaps the first alignment mark.

### CROSS-REFERENCE TO RELATED APPLICATION(S)

This application claims priority to and benefits of Korean Patent Application No. 10-2023-0087715 under 35 U.S.C. § 119 filed on Jul. 6, 2023, in the Korean Intellectual Property Office, the entire contents of which are incorporated herein by reference.

### BACKGROUND

### 1. Technical Field

The disclosure relates to a display device.

### 2. Description of the Related Art

With the advancement of the information age, the demand for a display device for displaying an image has increased with various forms. The display device may be a flat panel display device such as a liquid crystal display device, a field emission display device and a light emitting display device. The light emitting display device may include an organic light emitting display device that may include an organic light emitting diode element as a light emitting element, or a light emitting diode display device that may include an inorganic light emitting diode element such as a light emitting diode (LED) as a light emitting element.

In case of a display device for a vehicle, in case that an image displayed on the display device for a vehicle, which is placed in front of a driver or passenger, is reflected on a windshield at night, since it may interfere with the driver's driving, it is necessary to control a viewing angle of the image displayed on the display device for a vehicle. For privacy protection, it is necessary to control the viewing angle of the image displayed on the display device for a vehicle so that the image displayed on the display device for a vehicle, which is placed in front of the driver, is not provided to the passenger.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An object of the disclosure is to provide a display device that improves the degree of recognition of an alignment mark.

Another object of the disclosure is to provide a display device that improves alignment accuracy between members during a bonding process.

The objects of the disclosure are not limited to those mentioned above and additional objects of the disclosure will be clearly understood by those skilled in the art from the following description of the disclosure.

According to an aspect of the disclosure, a display device may include a light emitting element layer disposed on a substrate; a light control layer disposed on the light emitting element layer, the light control layer including a light-transmitting film and a light-shielding film; and a first alignment mark between the substrate and the light control layer, wherein the light-transmitting film and the light-shielding film alternate with each other, the light control layer may include a light-shielding film removal area in which the light-shielding film is not disposed, and the light-shielding film removal area may overlap the first alignment mark.

In an embodiment, the first alignment mark may not overlap the light-shielding film.

In an embodiment, the light-shielding film may extend in at least a direction in a plan view, and the light-shielding film may be disconnected in the light-shielding film removal area.

In an embodiment, the display device may further comprise a display area including a plurality of light emitting elements and a non-display area on a side of the display area, wherein the light-shielding film removal area may be disposed in the non-display area.

In an embodiment, the light-shielding film removal area may have a light transmittance greater than a light transmittance of a part of the light control layer, the part of the light control layer being disposed in the display area.

In an embodiment, a width of the light-transmitting film in the light-shielding film removal area may be greater than a width of the light-transmitting film in the display area.

In an embodiment, a size of the light control layer may be greater than a size of the display area in a plan view.

In an embodiment, a size of the light-shielding film removal area may be greater than or equal to a size of the first alignment mark.

In an embodiment, the display device may further comprise a thin film transistor layer disposed between the substrate and the light emitting element layer, wherein the first alignment mark may be disposed on the thin film transistor layer.

In an embodiment, the display device may further comprise a touch sensor layer disposed between the light emitting element layer and the light control layer, wherein the first alignment mark may be disposed on the touch sensor layer.

In an embodiment, the display device may further comprise an upper member disposed on the light control layer, the upper member including a second alignment mark, wherein the second alignment mark may overlap the light-shielding film removal area.

In an embodiment, the first alignment mark may overlap the second alignment mark.

According to an aspect of the disclosure, a display device may include a light emitting element layer disposed on a substrate; a light control layer disposed on the light emitting element layer, the light control layer including a light-transmitting film and a light-shielding film; and an upper member disposed on the light control layer, the upper member including a first alignment mark, wherein the light-transmitting film and the light-shielding film alternate with each other, the light control layer may include a light-shielding film removal area in which the light-shielding film is not disposed, and the light-shielding film removal area may overlap the first alignment mark.

In an embodiment, the first alignment mark may not overlap the light-shielding film.

In an embodiment, the light-shielding film may extend in at least a direction in a plan view, and the light-shielding film may be disconnected in the light-shielding film removal area.

In an embodiment, a size of the light-shielding film removal area may be greater than or equal to a size of the first alignment mark.

According to an aspect of the disclosure, a display device may include a display area and a non-display area on a side of the display area; a light emitting element layer disposed on a substrate, and a light control layer disposed on the light emitting element layer, the light control layer including a light-transmitting film and a light-shielding film, wherein the light control layer may include, a plurality of transmissive areas in which the light-shielding film is not disposed; a plurality of non-transmissive areas in which the light-shielding film is disposed and which alternate with the plurality of transmissive areas; and a first area in which the light-shielding film is not disposed in the non-display area, and a width of the first area may be greater than a width of one of the plurality of transmissive areas.

In an embodiment, the display may further comprise an alignment mark on the non-display area, wherein the first area may overlap the alignment mark.

In an embodiment, a size of the first area may be greater than or equal to a size of the alignment mark.

In an embodiment, a size of the light control layer may be greater than a size of the display area in a plan view.

The display device according to one embodiment may improve the degree of recognition of an alignment mark.

The display device according to one embodiment may improve alignment accuracy between members during a bonding process.

The effects according to the embodiments of the disclosure are not limited to those mentioned above and more various effects are included in the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is an exploded perspective view illustrating a display device according to one embodiment;

FIG. 2 is a schematic plan view illustrating a display device according to one embodiment;

FIG. 3 is an exploded perspective view illustrating a display device according to an embodiment;

FIG. 4 is a schematic cross-sectional view illustrating a display device, which is taken along line X1-X1′ of FIG. 2;

FIG. 5 is a schematic cross-sectional view illustrating an example of a display panel according to one embodiment;

FIG. 6 is a schematic plan view illustrating a display panel according to one embodiment;

FIG. 7 is a schematic cross-sectional view taken along line X2-X2′ of FIG. 6;

FIGS. 8 and 9 are schematic cross-sectional views taken along line X3-X3′ of FIG. 6;

FIG. 10 is a schematic cross-sectional view illustrating a bonding process of a display device according to one embodiment;

FIG. 11 is a schematic plan view illustrating a display device according to an embodiment;

FIG. 12 is a schematic cross-sectional view taken along line X4-X4′ of FIG. 11;

FIG. 13 is a schematic cross-sectional view illustrating a bonding process of a display device according to an embodiment;

FIG. 14 is a schematic plan view illustrating an aligning process of a second alignment mark and a light-shielding film removal area of a display device according to an embodiment; and

FIGS. 15 to 17 are schematic plan views illustrating a display device according to other embodiments.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will also be understood that when a layer is referred to as being “on” another layer or substrate, it can be directly on the other layer or substrate, or intervening layers may also be present. The same reference numbers indicate the same components throughout the specification.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described in detail with reference to the accompanying drawings.

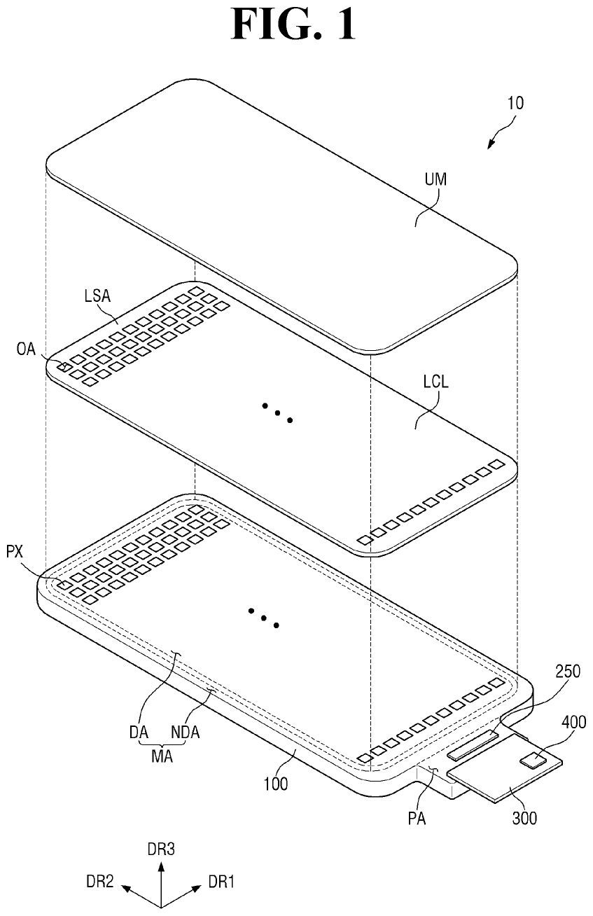

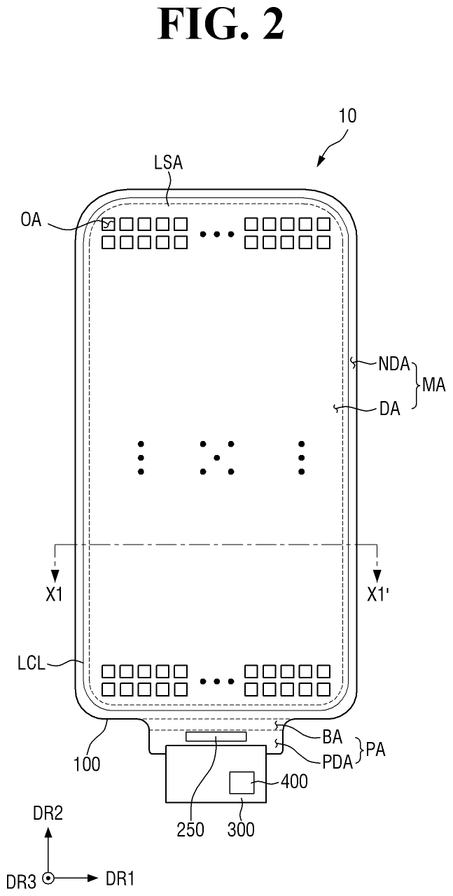

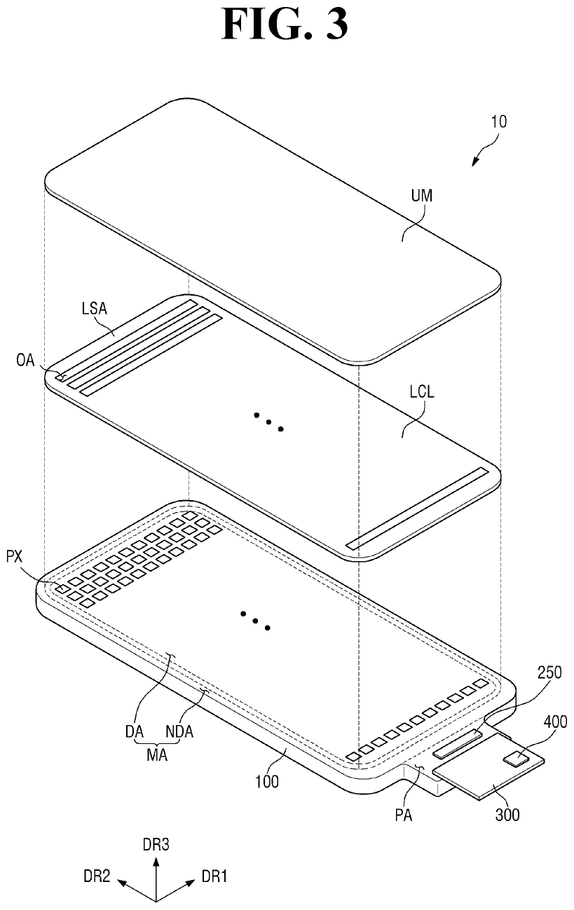

FIG. 1 is an exploded perspective view illustrating a display device according to one embodiment. FIG. 2 is a schematic plan view illustrating a display device according to one embodiment. FIG. 3 is an exploded perspective view illustrating a display device according to an embodiment. For convenience of description, an upper member UM is omitted in FIG. 2.

Referring to FIGS. 1 to 3, a display device 10 is a device that displays a moving image or a still image, and may be used as a display screen of various products such as a television, a laptop computer, a monitor, an advertising board and a device for Internet of things (IoT) as well as portable electronic devices such as a mobile phone, a smart phone, a tablet personal computer (PC), a smart watch, a watch phone, a mobile communication terminal, an electronic diary, an electronic book, a portable multimedia player (PMP), a navigator and an ultra mobile PC (UMPC). The display device 10 may be any one of an organic light emitting display device, a liquid crystal display device, a plasma display device, a field emission display device, an electrophoresis display device, an electrowetting display device, a quantum dot light emitting display device and a micro LED display device. The following description will be based on that the display device 10 is an organic light emitting display device, but the disclosure is not limited thereto.

The display device 10 according to one embodiment may include a display panel 100, a display driving circuit 250, a circuit board 300 and a touch driving circuit 400.

The display panel 100 may include pixels PX arranged or disposed in a first direction DR1 and a second direction DR2. Each of the pixels PX may have a planar shape such as a rectangular shape, a square shape or a rhombus shape. For example, as shown in the drawing, each of the pixels PX may have a square planar shape, but the disclosure is not limited thereto. Each of the pixels PX may have various shapes such as a polygonal shape, a circular shape and an oval shape on a plane.

In the shown drawing, the first direction DR1 and the second direction DR2 are horizontal directions, and intersect each other. For example, the first direction DR1 and the second direction DR2 may be orthogonal to each other. A third direction DR3 intersects the first direction DR1 and the second direction DR2, and may be, for example, a vertical direction orthogonal to the first direction DR1 and the second direction DR2.

The display panel 100 may include a main area MA and a protrusion area PA protruded from a side of the main area MA.

The main area MA may be formed in a rectangular shape having a short side in the first direction DR1 and a long side in the second direction DR2 intersecting the first direction DR1. A corner at which the short side in the first direction DR1 and the long side in the second direction DR2 meet may be rounded to have a selectable curvature or formed at a right angle. The planar shape of the display device 10 is not limited to the rectangular shape, and may be formed in another polygonal shape, a circular shape or an oval shape. The main area MA may be formed to be flat, but is not limited thereto. The main area MA may include a curved portion formed at left and right ends. The curved portion may have a constant curvature or a variable curvature.

The main area MA may include a display area DA in which pixels are formed to display an image and a non-display area NDA that is a peripheral area of the display area DA.

Scan lines, data lines and a power line, which are connected to the pixels, as well as the pixels may be disposed in the display area DA. In case that the main area MA may include a curved portion, the display area DA may be disposed in the curved portion. An image of the display panel 100 may be viewed even in the curved portion.

The non-display area NDA may be defined as an area from the outside of the display area DA to an edge of the display panel 100. A scan driver for applying scan signals to the scan lines, and link lines for connecting the data lines with the display driving circuit 250 may be disposed in the non-display area NDA.

The protrusion area PA may be protruded from a side of the main area MA. For example, as shown in FIG. 2, the protrusion area PA may be protruded from a lower side of the main area MA. A length of the protrusion area PA in the first direction DR1 may be shorter than a length of the main area MA in the first direction DR1.

The protrusion area PA may include a bending area BA and a pad area PDA. The pad area PDA may be disposed on a side of the bending area BA, and the main area MA may be disposed on another side of the bending area BA. For example, the pad area PDA may be disposed below the bending area BA, and the main area MA may be disposed above the bending area BA.

The display panel 100 may be flexibly formed to be curved, bent, folded or rolled. Therefore, the display panel 100 may be bent in a thickness direction, for example, the third direction DR3 in the bending area BA. A surface of the pad area PDA of the display panel 100 is directed upward before the display panel 100 is bent, but a surface of the pad area PDA of the display panel 100 is directed downward after the display panel 100 is bent. As a result, the pad area PDA is disposed below the main area MA, and thus may overlap the main area MA.

Pads electrically connected to the display driving circuit 250 and the circuit board 300 may be disposed in the pad area PDA of the display panel 100.

The display driving circuit 250 outputs signals and voltages for driving the display panel 100. For example, the display driving circuit 250 may supply data voltages to the data lines. The display driving circuit 250 may supply a power voltage to the power line and supply scan control signals to the scan driver. The display driving circuit 250 may be formed of an integrated circuit (IC), and may be mounted on the display panel 100 in the pad area PDA in a chip on glass (COG) mode, a chip on plastic (COP) mode or an ultrasonic bonding mode, but is not limited thereto. For example, the display driving circuit 250 may be mounted on the circuit board 300.

The pads may include display pads electrically connected to the display driving circuit 250 and touch pads electrically connected to the touch lines.

The circuit board 300 may be attached onto the pads by using an anisotropic conductive film. Therefore, lead lines of the circuit board 300 may be electrically connected to the pads. The circuit board 300 may be a flexible printed circuit board, a printed circuit board or a flexible film such as a chip on film.

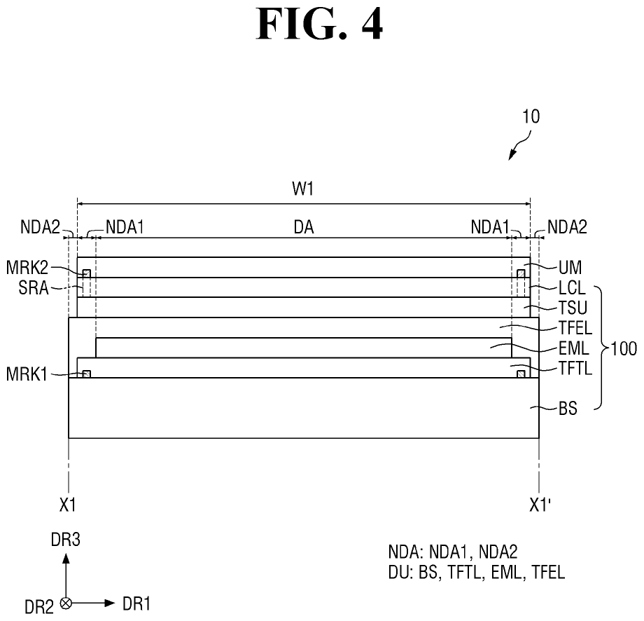

The touch driving circuit 400 may be connected to touch electrodes of a touch sensor layer TSU (see FIG. 4) of the display panel 100. The touch driving circuit 400 applies driving signals to the touch electrodes of the touch sensor layer TSU (see FIG. 4) and measures capacitance values of the touch electrodes. The drive signal may be a signal having driving pulses. The touch driving circuit 400 may determine whether a touch is input depending on the capacitance values, and may calculate touch coordinates to which a touch is input.

The touch driving circuit 400 may be disposed on the circuit board 300. The touch driving circuit 400 may be formed of an integrated circuit (IC) and mounted on the circuit board 300.

In the display device 10 according to an embodiment, the display panel 100 may further include a light control layer LCL.

The light control layer LCL may be directly disposed on the main area MA of the display panel 100. For example, the light control layer LCL may be embedded in the display panel 100 and disposed directly on the main area MA of the display panel 100. As the light control layer LCL is embedded in the display panel 100, a thickness and manufacturing cost of the display device 10 may be reduced as compared with the case that a separate light control film is attached.

However, the light control layer LCL is not limited to the above example, and the light control layer LCL may be configured separately from the display panel 100 and attached onto the display panel 100 in the form of a light control film. Hereinafter, for convenience of description, the case that the light control layer LCL is embedded in the display panel 100 will be described as an example.

In an embodiment, the light control layer LCL may be disposed over the display area DA and the non-display area NDA of the main area MA. For example, as shown in the drawing, a size of the light control layer LCL may be greater than that of the display area DA on a plane. Therefore, the light control layer LCL may be disposed over both the display area DA and the non-display area NDA.

The light control layer LCL may adjust a viewing angle of light emitted from the display panel 100. The light control layer LCL may include transmissive areas OA arranged or disposed in the first direction DR1 and the second direction DR2 and a non-transmissive area LSA surrounding the transmissive areas OA.

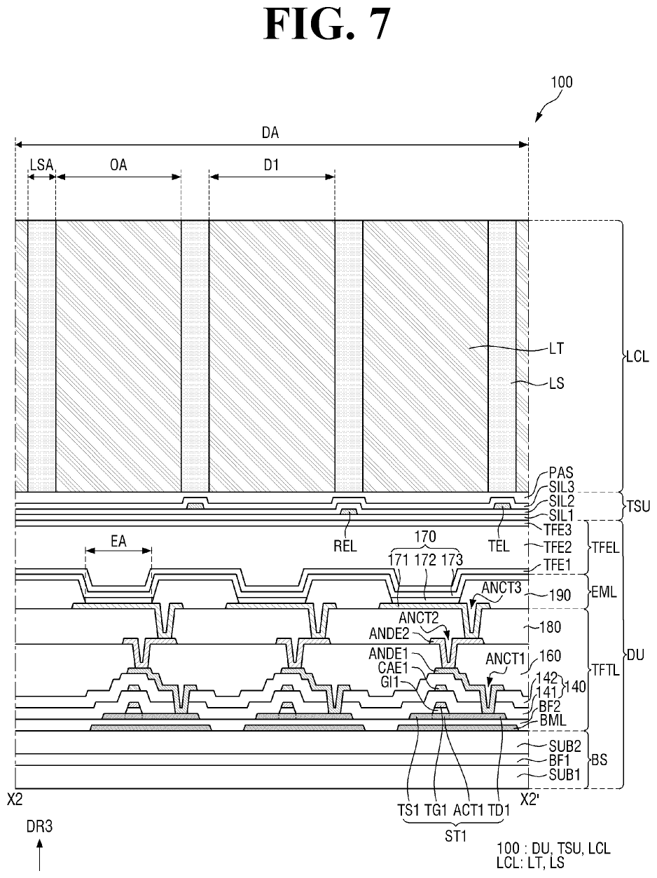

The transmissive areas OA may be areas in which a light-shielding film LS (see FIG. 7) is not disposed. The transmissive areas OA may be extended to an area, through which light is transmitted, along the third direction DR3.

Each of the transmissive areas OA may have a rectangular shape on a plane as shown in FIGS. 1 and 2, but is not limited thereto. Each of the transmissive areas OA may have a circular shape, an oval shape or a polygonal shape on a plane.

In an embodiment, the transmissive areas OA may have a shape extended in the first direction DR1 or the second direction DR2. For example, as shown in FIG. 3, the transmissive areas OA may be extended in the first direction DR1, and may be disposed along the second direction DR2. For another example, the transmissive areas OA may be extended in the second direction DR2, and may be disposed along the first direction DR1.

As shown in FIG. 1, in case that the transmissive areas OA are disposed along the first direction DR1 and the second direction DR2, a viewing angle may be controlled in both the first direction DR1 and the second direction DR2. As shown in FIG. 3, in case that the transmissive areas OA are disposed along the first direction DR1 or the second direction DR2, the viewing angle may be controlled in the first direction DR1 or the second direction DR2. For example, various modifications may be made in the arrangement and shape of the transmissive areas OA depending on a required control direction of the viewing angle.

The non-transmissive area LSA may be the remaining area of the light control layer LCL except the transmissive area OA. The non-transmissive area LSA may be an area in which the light-shielding film LS (see FIG. 7) is disposed.

In the drawing, the non-transmissive area LSA is shown as being disposed to surround the transmissive area OA, but is not limited thereto. In an embodiment, the non-transmissive area LSA may be extended in the same direction as the transmissive area OA, and may be disposed to be alternate with the transmissive area OA. For example, as shown in FIG. 3, in case that the transmissive area OA is extended in the first direction DR1, the non-transmissive area LSA may be extended in the first direction DR1, and may be disposed to be alternate with the transmissive area OA in the second direction DR2.

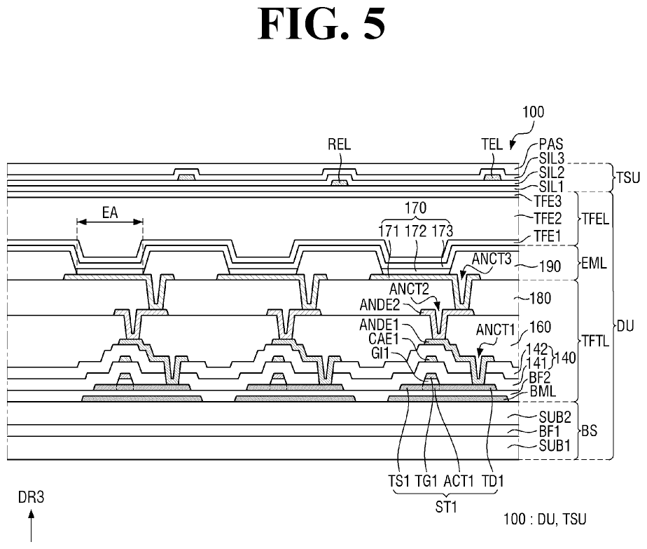

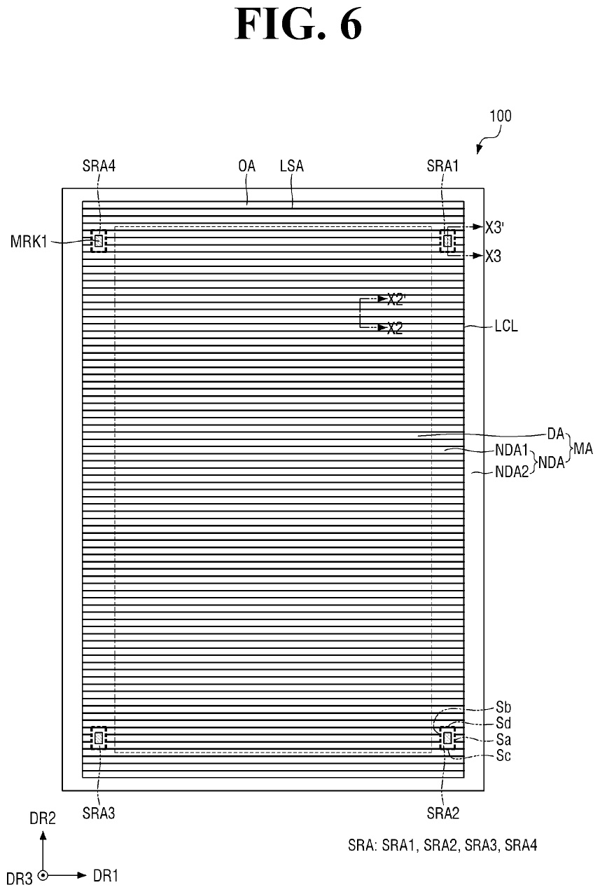

The light control layer LCL may include a light-shielding film LS (see FIG. 7) that shields light emitted from a light emitting layer 172 (see FIG. 5) of the display panel 100 and a light-transmitting film LT (see FIG. 7) that transmits the light. A detailed structure of the light control layer LCL will be described later with reference to FIG. 6.

The display device 10 may further include an upper member UM. The upper member UM may include functional layers such as an optical member and a cover window. The upper member UM may be additionally disposed on the light control layer LCL. The light control layer LCL and the upper member UM may be attached to each other by a transparent adhesive member such as a pressure sensitive adhesive (PSA) film and an optically clear adhesive (OCA) film.

In the drawing, a size of the upper member UM is shown as being the same as that of the light control layer LCL, but is not limited thereto. For example, the size of the upper member UM may be greater than the size of the light control layer LCL and the size of the display panel 100, and may cover both the light control layer LCL and an upper surface and sides of the display panel 100.

FIG. 4 is a schematic cross-sectional view illustrating a display device taken along the line X1-X1′ of FIG. 2.

Referring to FIG. 4, the display device 10 may include a display panel 100 in which the light control layer LCL is embedded. The display panel 100 may include a display layer DU, a touch sensor layer TSU and a light control layer LCL. The display layer DU may include a base member BS, a thin film transistor layer TFTL, a light emitting element layer EML and a thin film encapsulation layer TFEL.

The base member BS may include a substrate. The substrate may be made of an insulating material such as glass, quartz or a polymer resin. An example of the polymer material include polyethersulfone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP) or their combination. By way of example, the substrate may include a metal material.

The substrate may be a rigid substrate, or may be a flexible substrate capable of being subjected to bending, folding, rolling or the like within the spirit and the scope of the disclosure. In case that the substrate is a flexible substrate, the substrate may be formed of polyimide (PI), but is not limited thereto.

The thin film transistor layer TFTL may be disposed on the base member BS. Scan lines, data lines, power lines, scan control lines, routing lines connecting the pads with the data lines, etc. as well as thin film transistors of the respective pixels may be formed in the thin film transistor layer TFTL. Each of the thin film transistors may include a gate electrode, a semiconductor layer, a source electrode and a drain electrode.

The thin film transistor layer TFTL may be disposed in the display area DA and the non-display area NDA. In detail, the thin film transistors of the respective pixels, the scan lines, the data lines and the power lines of the thin film transistor layer TFTL may be disposed in the display area DA. The scan control lines and the link lines of the thin film transistor layer TFTL may be disposed in the non-display area NDA.

The light emitting element layer EML may be disposed on the thin film transistor layer TFTL. The light emitting element layer EML may include pixels, which include a first electrode, a light emitting layer and a second electrode, and a pixel defining layer for defining the pixels. The light emitting layer may be an organic light emitting layer that may include an organic material. The light emitting layer may include a hole transporting layer, an organic light emitting layer and an electron transporting layer. In case that a selectable voltage is applied to the first electrode through the thin film transistor of the thin film transistor layer TFTL and a cathode voltage is applied to the second electrode, holes and electrons are moved to the organic light emitting layer through the hole transporting layer and the electron transporting layer, respectively and are combined with each other in the organic light emitting layer to emit light. The pixels of the light emitting element layer EML may be disposed in the display area DA.

The thin film encapsulation layer TFEL may be disposed on the light emitting element layer EML. The thin film encapsulation layer TFEL may serve to prevent oxygen or moisture from being permeated into the light emitting element layer EML. To this end, the thin film encapsulation layer TFEL may include at least one inorganic layer. The inorganic layer may be a silicon nitride layer, a silicon oxynitride layer, a silicon oxide layer, a titanium oxide layer or an aluminum oxide layer, but is not limited thereto. The thin film encapsulation layer TFEL may serve to protect the light emitting element layer EML from particles such as dust. To this end, the thin film encapsulation layer TFEL may include at least one organic layer. The organic layer may be an acryl resin, an epoxy resin, a phenolic resin, a polyamide resin or a polyimide resin, but is not limited thereto.

The thin film encapsulation layer TFEL may be disposed in both the display area DA and the non-display area NDA. In detail, the thin film encapsulation layer TFEL may be disposed to cover the light emitting element layer EML of the display area DA and the non-display area NDA and cover the thin film transistor layer TFTL of the non-display area NDA.

The touch sensor layer TSU may be disposed on the thin film encapsulation layer TFEL. Since the touch sensor layer TSU is disposed directly on the thin film encapsulation layer TFEL, the thickness of the display device 10 may be reduced as compared with the case that a separate touch panel including the touch sensor layer TSU is attached onto the thin film encapsulation layer TFEL.

The touch sensor layer TSU may include touch electrodes for sensing a touch of a user in a capacitance manner and touch lines for connecting the pads with the touch electrodes. For example, the touch sensor layer TSU may sense a touch of a user in a self-capacitance manner or a mutual capacitance manner.

The touch electrodes of the touch sensor layer TSU may be disposed in a touch sensor area that overlaps the display area DA. The touch lines of the touch sensor layer TSU may be disposed in a touch peripheral area that overlaps the non-display area NDA.

The light control layer LCL may be disposed on the touch sensor layer TSU. The light control layer LCL may be disposed in the display area DA and the non-display area NDA. The light control layer LCL may serve to absorb or shield light moving out of a selectable angle with respect to the third direction DR3 among the lights emitted from the light emitting element layer EML. For example, the light control layer LCL may control a viewing angle.

The display device 10 may further include an upper member UM. The upper member UM may include functional layers such as an optical member and a cover window. The upper member UM may be additionally disposed on the light control layer LCL. The light control layer LCL and the upper member UM may be attached to each other by a transparent adhesive member such as a pressure sensitive adhesive (PSA) film and an optically clear adhesive (OCA) film.

In an embodiment, the display panel 100 may include a display area DA and a non-display area NDA. The non-display area NDA1 may include a first non-display area NDA1 and a second non-display area NDA2.

The first non-display area NDA1 may be an area that overlaps at least a portion of the light control layer LCL. The second non-display area NDA2 may be an area that does not overlap the light control layer LCL.

The first non-display area NDA1 may be disposed on a side of the display area DA. The first non-display area NDA1 may be disposed to surround the display area DA. The second non-display area NDA2 may be disposed on a side of the first non-display area NDA1. The second non-display area NDA2 may be disposed to surround the first non-display area NDA1.

In an embodiment, the thin film transistor layer TFTL, the touch sensor layer TSU, the light control layer LCL and the upper member UM may be disposed over the display area DA and the first non-display area NDA1. For example, a width W1 of the thin film transistor layer TFTL, the touch sensor layer TSU, the light control layer LCL and the upper member UM may be greater than a width of the display area DA.

The display device 10 may include a first alignment mark MRK1 and a second alignment mark MRK2, which are disposed in the first non-display area NDA1.

The first alignment mark MRK1 may be included in the display panel 100. For example, the first alignment mark MRK1 may be disposed in the thin film transistor layer TFTL of the display panel 100. The second alignment mark MRK2 may be included in the upper member UM.

In an embodiment, the first alignment mark MRK1 may be formed of the same material on the same layer as at least one of line layers of the thin film transistor layer TFTL, which will be described later. For example, the first alignment mark MRK1 may be formed of the same material on the same layer as at least one of line layers such as a lower metal layer BML (see FIG. 5), a first gate electrode TG1 (see FIG. 5), a first capacitor electrode CAE1 (see FIG. 5), a first anode connection electrode ANDE1 (see FIG. 5) or a second anode connection electrode ANDE2 (see FIG. 5), which will be described later with reference to FIG. 5.

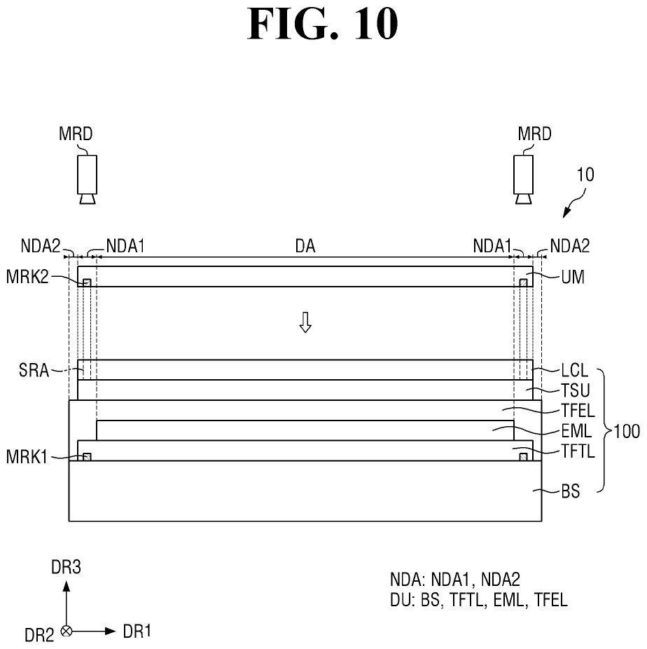

The first alignment mark MRK1 and the second alignment mark MRK2 may overlap each other in the third direction DR3. In the display device 10 according to an embodiment, the first alignment mark MRK1 and the second alignment mark MRK2 may be recognized through a recognition device MRD (see FIG. 10) during a bonding process of the upper member UM and the display panel 100, so that the upper member UM and the display panel 100 may be correctly aligned.

In the display device 10 according to an embodiment, the light control layer LCL may include a light-shielding film removal area SRA in order to improve the degree of recognition of the first alignment mark MRK1 and the second alignment mark MRK2.

The light-shielding film removal area SRA may be an area in which the light-shielding film LS (see FIG. 7), which will be described later, is not disposed. The light-transmitting film LT (see FIG. 7) may be disposed in the light-shielding film removal area SRA. The light-shielding film removal area SRA may have higher light transmittance than other areas in which the light-shielding film LS is disposed.

The light-shielding film removal area SRA may overlap the first alignment mark MRK1 and the second alignment mark MRK2 in the third direction DR3. Therefore, alignment accuracy between the upper member UM and the display panel 100 may be improved during a bonding process of the display device 10.

In an embodiment, a size of the light-shielding film removal area SRA may be greater than or equal to that of the first alignment mark MRK1 and the second alignment mark MRK2.

In the disclosure, the bonding process has been described based on the upper member UM disposed on the display panel 100, but is not limited thereto. For example, even though the lower member disposed below the display panel 100 is used for the bonding process, the second alignment mark MRK2 included in the lower member and the first alignment mark MRK1 included in the display panel 100 may be recognized in the same manner as the upper member UM.

FIG. 5 is a schematic cross-sectional view illustrating an example of a display panel according to one embodiment. In FIG. 5, for convenience of description, the light control layer LCL is omitted.

Referring to FIG. 5, the display panel 100 may include a display layer DU and a touch sensor layer TSU. The display layer DU may include a base member BS, a thin film transistor layer TFTL, a light emitting element layer EML and a thin film encapsulation layer TFEL.

The base member BS may include a first substrate SUB1, a first buffer layer BF1 disposed on the first substrate SUB1, and a second substrate SUB2 disposed on the first buffer layer BF1.

The first substrate SUB1 and the second substrate SUB2 may be made of an insulating material such as glass, quartz or a polymer resin. An example of the polymer material include polyethersulfone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP) or their combination. By way of example, the substrate may include a metal material.

Each of the first substrate SUB1 and the second substrate SUB2 may be a rigid substrate, or may be a flexible substrate capable of being subjected to bending, folding, rolling or the like within the spirit and the scope of the disclosure. In case that the substrate is a flexible substrate, the substrate may be formed of polyimide (PI), but is not limited thereto.

The first buffer layer BF1 may be a layer for protecting the first thin film transistor ST1 and the light emitting layer 172 from moisture permeated through the first substrate SUB1 and the second substrate SUB2, which are vulnerable to moisture permeation. The first buffer layer BF1 may include inorganic layers that may be alternately stacked each other. For example, the first buffer layer BF1 may be formed of a multi-layer in which one or more inorganic layers of a silicon nitride layer, a silicon oxynitride layer, a silicon oxide layer, a titanium oxide layer and an aluminum oxide layer may be alternately stacked each other.

The thin film transistor layer TFTL may include a lower metal layer BML, a second buffer layer BF2, a first thin film transistor ST1, a first gate insulating layer GI1, a first interlayer insulating layer 141, a first capacitor electrode CAE1, a second interlayer insulating layer 142, a first anode connection electrode ANDE1, a first organic layer 160, a second anode connection electrode ANDE2, and a second organic layer 180. An interlayer insulating layer 140 may include the first interlayer insulating layer 141 and the second interlayer insulating layer 142.

The lower metal layer BML may be disposed on the second substrate SUB2. The lower metal layer BML may be disposed to overlap a first active layer ACT1 of the first thin film transistor ST1 in the third direction DR3 in order to prevent a leakage current from occurring in case that light is incident on the first active layer ACT1 of the first thin film transistor ST1. The lower metal layer BML may be formed of a single layer or multi-layer made of one of molybdenum (Mo), aluminum (Al), chromium (Cr), gold (Au), titanium (Ti), nickel (Ni), neodymium (Nd) and copper (Cu), or their alloy. The lower metal layer BML may be omitted.

The second buffer layer BF2 may be disposed on the lower metal layer BML. The second buffer layer BF2 is a layer for protecting the first thin film transistor ST1 and the light emitting layer 172 from moisture permeated through the first substrate SUB1 and the second substrate SUB2, which are vulnerable to moisture permeation. The second buffer layer BF2 may include inorganic layers that may be alternately stacked each other. For example, the second buffer layer BF2 may be formed of a multi-layer in which one or more inorganic layers of a silicon nitride layer, a silicon oxynitride layer, a silicon oxide layer, a titanium oxide layer and an aluminum oxide layer may be alternately stacked each other.

The first active layer ACT1 of the first thin film transistor ST1 may be disposed on the second buffer layer BF2. The first active layer ACT1 of the first thin film transistor ST1 may include polycrystalline silicon, monocrystalline silicon, low temperature polycrystalline silicon, amorphous silicon or an oxide semiconductor. Since the first active layer ACT1 of the first thin film transistor ST1 exposed without being covered by the first gate insulating layer GI1 is doped with impurities or ions, the first active layer ACT1 of the first thin film transistor ST1 may have conductivity. Therefore, a first source electrode TS1 and a first drain electrode TD1 of the first active layer ACT1 of the first thin film transistor ST1 may be formed.

The first gate insulating layer GI1 may be disposed on the first active layer ACT1 of the first thin film transistor ST1. In FIG. 5, the first gate insulating layer GI1 is illustrated as being disposed between the first gate electrode TG1 and the first active layer ACT1 of the first thin film transistor ST1, but is not limited thereto. The first gate insulating layer GI1 may be disposed between the first interlayer insulating layer 141 and the first active layer ACT1 and between the first interlayer insulating layer 141 and the second buffer layer BF2. The first gate insulating layer GI1 may be formed of an inorganic layer, for example, a silicon nitride layer, a silicon oxynitride layer, a silicon oxide layer, a titanium oxide layer or an aluminum oxide layer.

The first gate electrode TG1 of the first thin film transistor ST1 may be disposed on the first gate insulating layer GI1. The first gate electrode TG1 of the first thin film transistor ST1 may overlap the first active layer ACT1 in the third direction DR3. The first gate electrode TG1 of the first thin film transistor ST1 may be formed of a single layer or multi-layer made of any one of molybdenum (Mo), aluminum (Al), chromium (Cr), gold (Au), titanium (Ti), nickel (Ni), neodymium (Nd) and copper (Cu), or their alloy.

The first interlayer insulating layer 141 may be disposed on the first gate electrode TG1 of the first thin film transistor ST1. The first interlayer insulating layer 141 may be formed of an inorganic layer, for example, a silicon nitride layer, a silicon oxynitride layer, a silicon oxide layer, a titanium oxide layer or an aluminum oxide layer. The first interlayer insulating layer 141 may include inorganic layers.

The first capacitor electrode CAE1 may be disposed on the first interlayer insulating layer 141. The first capacitor electrode CAE1 may overlap the first gate electrode TG1 of the first thin film transistor ST1 in the third direction (Z-axis direction). Since the first interlayer insulating layer 141 has a selectable dielectric constant, a capacitor may be formed by the first capacitor electrode CAE1, the first gate electrode TG1 and the first interlayer insulating layer 141 disposed between the first capacitor electrode CAE1 and the first gate electrode TG1. The first capacitor electrode CAE1 may be formed of a single layer or multi-layer made of any one of molybdenum (Mo), aluminum (Al), chromium (Cr), gold (Au), titanium (Ti), nickel (Ni), neodymium (Nd) and copper (Cu), or their alloy.

The second interlayer insulating layer 142 may be disposed on the first capacitor electrode CAE1. The second interlayer insulating layer 142 may be formed of an inorganic layer, for example, a silicon nitride layer, a silicon oxynitride layer, a silicon oxide layer, a titanium oxide layer or an aluminum oxide layer. The second interlayer insulating layer 142 may include inorganic layers.

The first anode connection electrode ANDE1 may be disposed on the second interlayer insulating layer 142. The first anode connection electrode ANDE1 may be connected to the first drain electrode TD1 of the first thin film transistor ST1 through a first anode contact hole ANCT1, which exposes the first drain electrode TD1 of the first thin film transistor ST1, by passing through the first interlayer insulating layer 141 and the second interlayer insulating layer 142. The first anode connection electrode ANDE1 may be formed of a single layer or multi-layer made of any one of molybdenum (Mo), aluminum (Al), chromium (Cr), gold (Au), titanium (Ti), nickel (Ni), neodymium (Nd) and copper (Cu), or their alloy.

The first organic layer 160 for planarization may be disposed on the first anode connection electrode ANDE1. The first organic layer 160 may be formed of an organic layer such as acryl resin, epoxy resin, phenolic resin, polyamide resin and polyimide resin.

The second anode connection electrode ANDE2 may be disposed on the first organic layer 160. The second anode connection electrode ANDE2 may be connected to the second anode connection electrode ANDE2 through a second anode contact hole ANCT2, which exposes the first anode connection electrode ANDE1, by passing through the first organic layer 160. The second anode connection electrode ANDE2 may be formed of a single layer or multi-layer made of any one of molybdenum (Mo), aluminum (Al), chromium (Cr), gold (Au), titanium (Ti), nickel (Ni), neodymium (Nd) and copper (Cu), or their alloy.

The second organic layer 180 may be disposed on the second anode connection electrode ANDE2. The second organic layer 180 may be formed of an organic layer such as acryl resin, epoxy resin, phenolic resin, polyamide resin and polyimide resin.

In FIG. 5, the first thin film transistor ST1 is formed in a top gate mode in which the first gate electrode TG1 is positioned above the first active layer ACT1, but is not limited thereto. The first thin film transistor ST1 may be formed in a bottom gate mode in which the first gate electrode TG1 is disposed below the first active layer ACT1 or a double gate mode in which the first gate electrode TG1 is disposed above and below the first active layer ACT1.

The light emitting element layer EML may be disposed on the second organic layer 180. The light emitting element layer EML may include light emitting elements 170 and a bank 190. Each of the light emitting elements 170 may include a first light emitting electrode 171, a light emitting layer 172 and a second light emitting electrode 173.

The first light emitting electrode 171 may be formed on the second organic layer 180. The first light emitting electrode 171 may be connected to the second anode connection electrode ANDE2 through a third anode contact hole ANCT3, which exposes the second anode connection electrode ANDE2, by passing through the second organic layer 180.

The first light emitting electrode 171 may be formed on the second organic layer 180. The first light emitting electrode 171 may be connected to the second anode connection electrode ANDE2 through a third anode contact hole ANCT3, which exposes the second anode connection electrode ANDE2, by passing through the second organic layer 180.

In a top emission structure in which light is emitted toward the second light emitting electrode 173 based on the light emitting layer 172, the first light emitting electrode 171 may be formed of a metal material having high reflectivity, such as a stacked structure (Ti/Al/Ti) of aluminum and titanium, a stacked structure (ITO/AI/ITO) of aluminum and ITO, an APC alloy and a stacked structure (ITO/APC/ITO) of an APC alloy and ITO. The APC alloy is an alloy of silver (Ag), palladium (Pd) and copper (Cu).

The bank 190 may be formed to partition the first light emitting electrode 171 on the second organic layer 180 to serve to define a light emission area EA. The bank 190 may be formed to cover an edge of the first light emitting electrode 171. The bank 190 may be formed of an organic layer such as acryl resin, epoxy resin, phenolic resin, polyamide resin and polyimide resin.

The light emission area EA refers to an area in which the first light emitting electrode 171, the light emitting layer 172 and the second light emitting electrode 173 are sequentially stacked each other so that holes from the first light emitting electrode 171 and electrons from the second light emitting electrode 173 are combined with each other in the light emitting layer 172 to emit light.

The light emitting layer 172 is formed on the first light emitting electrode 171 and the bank 190. The light emitting layer 172 may include an organic material to emit light of a selectable color. For example, the light emitting layer 172 may include a hole transporting layer, an organic material layer, and an electron transporting layer.

The second light emitting electrode 173 may be disposed on the light emitting layer 172. The second light emitting electrode 173 may be formed to cover the light emitting layer 172. The second light emitting electrode 173 may be a common layer commonly formed in all of the light emission areas EA. In an embodiment, although not shown, a capping layer may be formed on the second light emitting electrode 173.

In the top emission structure, the second light emitting electrode 173 may be formed of a transparent conductive oxide (TCO) such as indium tin oxide (ITO) and indium zinc oxide (IZO) or a semi-transmissive conductive material such as magnesium (Mg), silver (Ag) or an alloy of magnesium (Mg) and silver (Ag). In case that the second light emitting electrode 173 is formed of a semi-transmissive conductive material, light emission efficiency may be enhanced by a micro cavity.

The thin film encapsulation layer TFEL may be disposed on the second light emitting electrode 173. The thin film encapsulation layer TFEL may include at least one inorganic layer to prevent oxygen or moisture from being permeated into the light emitting element layer. The thin film encapsulation layer TFEL may also include at least one organic layer to protect the light emitting element layer from particles such as dust. For example, the thin film encapsulation layer TFEL may include a first encapsulation layer TFE1, a second encapsulation layer TFE2, and a third encapsulation layer TFE3.

The first encapsulation layer TFE1 (for example, a first inorganic encapsulation layer) may be disposed on the second light emitting electrode 173. The first encapsulation layer TFE1 may be an inorganic layer of a single layer or a multi-layer. The first encapsulation layer TFE1 may be formed of a multi-layer or single layer, in which one or more inorganic layers of a silicon nitride layer, a silicon oxynitride layer, a silicon oxide layer, a titanium oxide layer and an aluminum oxide layer may be alternately stacked each other.

The second encapsulation layer TFE2 (for example, a first organic encapsulation layer) may be disposed on the first encapsulation layer TFE1. The second encapsulation layer TFE2 may be an organic layer of a single layer or a multi-layer. The second encapsulation layer TFE2 may include a polymer-based material. The polymer-based material may include polyethylene terephthalate, polyethylene naphthalate, polycarbonate, polyimide, polyethylene sulfonate, polyoxymethylene, polyarylate, hexamethyldisiloxane, acrylic resin (for example, polymethyl methacrylate, polyacrylic acid, etc.) or any combination thereof.

The third encapsulation layer TFE3 (for example, a second inorganic encapsulation layer) may be disposed on the second encapsulation layer TFE2. The third encapsulation layer TFE3 may be an inorganic layer of a single layer or a multi-layer. The third encapsulation layer TFE3 may include the same material as that of the first encapsulation layer TFE1. For example, the third encapsulation layer TFE3 may be formed of a multi-layer or single layer, in which one or more inorganic layers of a silicon nitride layer, a silicon oxynitride layer, a silicon oxide layer, a titanium oxide layer and an aluminum oxide layer may be alternately stacked each other.

The touch sensor layer TSU may be disposed on the thin film encapsulation layer TFEL. The touch sensor layer TSU may include touch electrodes for sensing a touch of a user in a capacitance manner and touch lines for connecting the touch electrodes with the touch driving circuit. For example, the touch sensor layer TSU may sense a touch of a user in a mutual capacitance manner or a self-capacitance manner.

In an embodiment, the touch sensor layer TSU may be disposed on a separate substrate disposed on the display layer DU. The substrate for supporting the touch sensor layer TSU may be an encapsulation member for encapsulating the display layer DU.

The touch electrodes of the touch sensor layer TSU may be disposed in the touch sensor area that overlaps the display area. The touch lines of the touch sensor layer TSU may be disposed in the touch peripheral area that overlaps the non-display area.

The touch sensor layer TSU may include a first touch insulating layer SIL1, a first touch electrode REL, a second touch insulating layer SIL2, a second touch electrode TEL, and a third touch insulating layer SIL3.

The first touch insulating layer SIL1 may be disposed on the thin film encapsulation layer TFEL. The first touch insulating layer SIL1 may have insulating and optical functions. The first touch insulating layer SIL1 may include at least one inorganic layer. For example, the first touch insulating layer SIL1 may be an inorganic layer that may include at least one of a silicon nitride layer, a silicon oxynitride layer, a silicon oxide layer, a titanium oxide layer or an aluminum oxide layer. Optionally, the first touch insulating layer SIL1 may be omitted.

The first touch electrode REL may be disposed on the first touch insulating layer SIL1. The first touch electrode REL may not overlap the light emitting element 170. The first touch electrode REL may be formed of a single layer of molybdenum (Mo), titanium (Ti), copper (Cu), aluminum (Al) or indium tin oxide (ITO), or may be formed of a stacked structure (Ti/Al/Ti) of aluminum and titanium, a stacked structure (ITO/AI/ITO) of aluminum and ITO, an APC alloy or a stacked structure (ITO/APC/ITO) of an APC alloy and ITO.

The second touch insulating layer SIL2 may cover the first touch electrode REL and the first touch insulating layer SIL1. The second touch insulating layer SIL2 may have insulating and optical functions. For example, the second touch insulating layer SIL2 may be formed of a material that may be used to form the first touch insulating layer SIL1, e.g., as discussed herein.

The second touch electrode TEL may be disposed on the second touch insulating layer SIL2. The second touch electrode TEL may not overlap the light emitting element 170. The second touch electrode TEL may be formed of a single layer of molybdenum (Mo), titanium (Ti), copper (Cu), aluminum (Al) or indium tin oxide (ITO), or may be formed of a stacked structure (Ti/Al/Ti) of aluminum and titanium, a stacked structure (ITO/AI/ITO) of aluminum and ITO, an APC alloy or a stacked structure (ITO/APC/ITO) of an APC alloy and ITO.

The third touch insulating layer SIL3 may cover the second touch electrode TEL and the second touch insulating layer SIL2. The third touch insulating layer SIL3 may have insulating and optical functions. The third touch insulating layer SIL3 may be formed of a material that may be used to form the second touch insulating layer SIL2, e.g., as discussed herein.

In an embodiment, the first touch insulating layer SIL1, the second touch insulating layer SIL2 and the third touch insulating layer SIL3 may be organic layers. For example, the first touch insulating layer SIL1, the second touch insulating layer SIL2 and the third touch insulating layer SIL3 may be organic layers such as acryl resin, epoxy resin, phenolic resin, polyamide resin and polyimide resin.

The touch sensor layer TSU may further include a planarization layer PAS for planarization. The planarization layer PAS may be formed of an organic layer such as acryl resin, epoxy resin, phenolic resin, polyamide resin and polyimide resin.

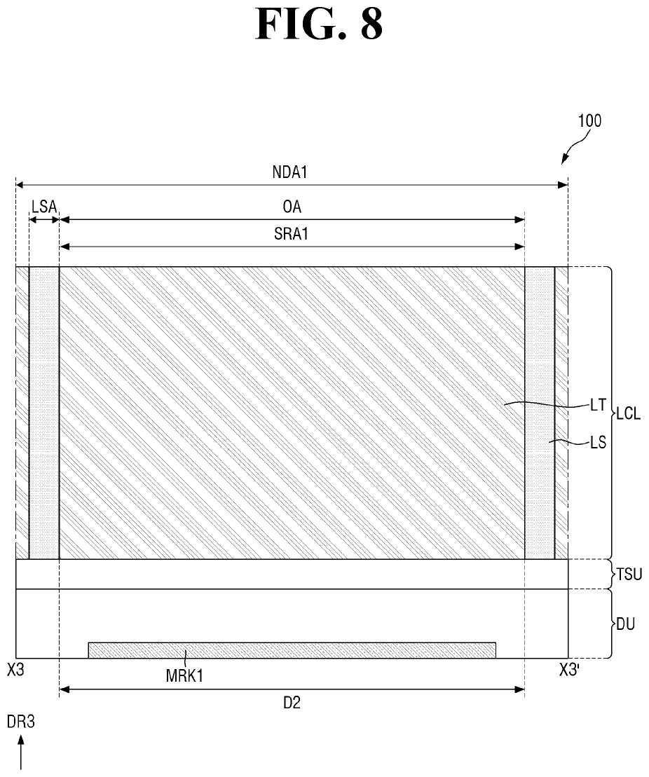

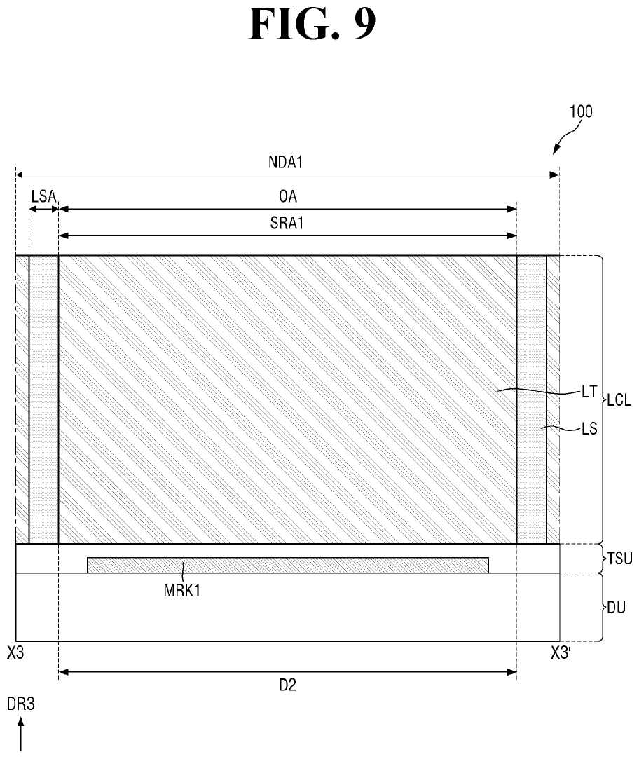

FIG. 6 is a schematic plan view illustrating a display panel according to one embodiment. FIG. 7 is a schematic cross-sectional view taken along line X2-X2′ of FIG. 6. FIGS. 8 and 9 are schematic cross-sectional views taken along the line X3-X3′ of FIG. 6.

In FIG. 6, a case that the transmissive area OA and the non-transmissive area LSA are extended in the first direction DR1 is shown as an example like the display device according to the embodiment of FIG. 3. Hereinafter, for convenience of description, the case that the transmissive area OA and the non-transmissive area LSA are extended in the first direction DR1 will be described as an example. For convenience of description, the main area MA of the display panel 100 is only shown in FIG. 6, and the protrusion area PA is omitted.

Referring to FIGS. 6 to 9 in addition to FIGS. 1 to 3, the display panel 100 may include a display area DA and a non-display area NDA. The non-display area NDA may include a first non-display area NDA1 and a second non-display area NDA2. The light control layer LCL of the display panel 100 may be disposed over the display area DA and the first non-display area NDA1.

The display panel 100 may include a transmissive area OA and a non-transmissive area LSA. The transmissive area OA may be an area in which the light-shielding film LS of the light control layer LCL is not disposed. The non-transmissive area LSA may be an area in which the light-shielding film LS of the light control layer LCL is disposed. The light-transmitting film LT may be disposed in the non-transmissive area LSA.

In an embodiment, as shown in the drawing, the transmissive area OA and the non-transmissive area LSA may be extended along the first direction DR1. The transmissive area OA and the non-transmissive area LSA may be alternately disposed in the second direction DR2.

As shown in FIG. 7, the light control layer LCL may be disposed on the touch sensor layer TSU. The light control layer LCL may control a viewing angle of light emitted from the light emitting layer 172. For example, in case that the light emitted from the light emitting layer 172 moves in the third direction DR3 at a selectable angle or less, the light may be emitted to the outside. On the other hand, in case that the light emitted from the light emitting layer 172 moves in the third direction DR3 by exceeding the selectable angle, the light may be absorbed or shielded by the light-shielding film LS and thus may not be emitted to the outside.

The light control layer LCL may include a light-shielding film LS and a light-transmitting film LT.

The light-shielding film LS may be disposed on the touch sensor layer TSU. The light-shielding film LS may be disposed in the non-transmissive area LSA. In one embodiment, as shown in FIG. 3, the light-shielding film LS may be disposed to be alternate with the light-transmitting film LT in the first direction DR1 or the second direction DR2. In an embodiment, the light-shielding film LS may include openings disposed in the transmissive area OA as shown in FIG. 1. The light-shielding film LS may surround the light-transmitting film LT.

The light-shielding film LS may absorb or shield the light emitted from the light emitting layer 172. The light-shielding film LS may include a light-shielding organic material. For example, the light-shielding film LS is a photosensitive resin capable of absorbing or shielding light, and may include an organic material containing an organic black pigment such as carbon black.

The light-transmitting film LT may be disposed on the touch sensor layer TSU. The light-transmitting film LT may be disposed in the transmissive area OA. In one embodiment, as shown in FIG. 3, the light-transmitting film LT may be disposed to be alternate with the light-shielding film LS in the first direction DR1 or the second direction DR2. In an embodiment, as shown in FIG. 1, the light-transmitting film LT may be disposed in the opening of the light-shielding film LS, and may be surrounded by the light-shielding film LS.

The light-transmitting film LT may transmit the light emitted from the light emitting layer 172. The light-transmitting film LT may include a transparent organic material. For example, the light-transmitting film LT may include an organic layer such as an acryl resin, an epoxy resin, a phenolic resin, a polyamide resin and a polyimide resin. In an embodiment, the light-transmitting film LT may include silicon oxynitride or silicon oxide.

The light control layer LCL may include a light-shielding film removal area SRA disposed in the first non-display area NDA. The light-shielding film removal area SRA may be an area in which the light-shielding film LS is not disposed. The light-transmitting film LT may be disposed in the light-shielding film removal area SRA. The light-shielding film removal area SRA may have higher light transmittance than other areas in which the light-shielding film LS is disposed.

In an embodiment, the light-shielding film removal area SRA may be defined by connecting disconnected portions of the light-shielding film LS. For example, the light-shielding film LS extended in the first direction DR1 may be partially disconnected in the light-shielding film removal area SRA. A first side Sa and a second side Sb of the light-shielding film removal area SRA may be extended in the second direction DR2 based on both ends in which the light-shielding film LS is disconnected in the first direction DR1. A third side Sc and a fourth side Sd of the light-shielding film removal area SRA may be extended in the first direction DR1 along the light-shielding film LS, which is closest to the disconnected light-shielding film, among the light-shielding films LS that are not disconnected.

However, the disclosure is not limited to the above examples. In case that the light-shielding film LS is extended in the first direction DR1 and the second direction DR2 and disposed in a mesh shape, the light-shielding film removal area SRA may be defined based on each end of the light-shielding film LS disconnected in the first direction DR1 and the second direction DR2. The light-shielding film removal area SRA may be defined in various shapes such as a circular shape as well as a rectangular shape.

In one embodiment, as shown in FIG. 6, the light-shielding film removal area SRA may include first to fourth light-shielding film removal areas SRA1, SRA2, SRA3 and SRA4. The first to fourth light-shielding film removal areas SRA1, SRA2, SRA3 and SRA4 may be disposed to be adjacent to each corner of the first non-display area NDA1. For example, the first light-shielding film removal area SRA1 may be disposed at a side in the first direction DR1 and a corner in the second direction DR2, and the second light-shielding film removal area SRA2 may be disposed at a side in the first direction DR1 and another corner in the second direction DR2. The third light-shielding film removal area SRA3 may be disposed at another side in the first direction DR1 and another corner in the second direction DR2, and the fourth light-shielding film removal area SRA4 may be disposed at another side in the first direction DR1 and a corner in the second direction DR2.

The display panel 100 may include a first alignment mark MRK1. In the drawing, a shape of the first alignment mark MRK1 is shown as being rectangular on a plane, but is not limited thereto. For example, the first alignment mark MRK1 may have various shapes such as a T shape, an L shape and an O shape. Various modifications may be made in a shape of the second alignment mark MRK2 like the shape of the first alignment mark MRK1.

Each of the first to fourth light-shielding film removal areas SRA1, SRA2, SRA3 and SRA4 may overlap the first alignment mark MRK1 in the third direction DR3. Since the light-shielding film LS is not disposed in the first to fourth light-shielding film removal areas SRA1, SRA2, SRA3 and SRA4, the first to fourth light-shielding film removal areas SRA1, SRA2, SRA3 and SRA4 may have high transmittance. Therefore, the degree of recognition of the first alignment mark MRK1 is improved during the bonding process of the display device 10, whereby alignment accuracy with another member may be improved.

In an embodiment, as shown in FIGS. 7 and 8, a width D2 of the light-transmitting film LT in the light-shielding film removal area SRA may be greater than a width D1 of the light-transmitting film LT in the display area DA. A size of the light-shielding film removal area SRA may be greater than or equal to that of the first alignment mark MRK1.

As shown in FIG. 8, the first alignment mark MRK1 may be disposed in the display layer DU, but is not limited thereto. For example, as shown in FIG. 9, the first alignment mark MRK1 may be disposed in the touch sensor layer TSU.

In one embodiment, in case that the first alignment mark MRK1 is disposed in the display layer DU, the first alignment mark MRK1 may be formed of the same material on the same layer as at least one of the line layers of the thin film transistor layer TFTL or the line layers of the light emitting element layer EML. For example, the first alignment mark MRK1 may be formed of the same material on the same layer as at least one of the line layers such as the lower metal layer BML, the first gate electrode TG1, the first capacitor electrode CAE1, the first anode connection electrode ANDE1 and the second anode connection electrode ANDE2. For another example, the first alignment mark MRK1 may be formed of the same material on the same layer as at least one of the first light emitting electrode 171 or the second light emitting electrode 173, which is disposed in the light emitting element layer EML.

In an embodiment, in case that the first alignment mark MRK1 is disposed in the touch sensor layer TSU, the first alignment mark MRK1 may be formed of the same material on the same layer as at least one of the line layers of the touch sensor layer TSU. For example, the first alignment mark MRK1 may be formed of the same material on the same layer as at least one of the first touch electrode REL or the second touch electrode TEL.

FIG. 10 is a schematic cross-sectional view illustrating a bonding process of a display device according to one embodiment.

Referring to FIG. 10 in addition to FIGS. 6 to 9, the recognition device MRD may be disposed above or below the display device 10 during the bonding process of the display device 10. In the drawing, the recognition device MRD is shown as being disposed on the display device 10, but is not limited thereto.

The recognition device MRD may recognize the first alignment mark MRK1 of the display panel 100 and the second alignment mark MRK2 of the upper member UM. The recognition device MRD may check alignment of the first alignment mark MRK1 and the second alignment mark MRK2 during the bonding process of the display device 10, thereby checking alignment of each member. The recognition device MRD may be an optical device for recognizing light reflected from the first alignment mark MRK1 and the second alignment mark MRK2.

Since the light control layer LCL may include the light-shielding film LS, the light reflected from the first alignment mark MRK1 and the second alignment mark MRK2 may be distorted while passing through the light control layer LCL. Therefore, it may be difficult for the recognition device MRD to correctly recognize the first alignment mark MRK1 and the second alignment mark MRK2.

The display device 10 according to an embodiment may include the light-shielding film removal area SRA in the light control layer LCL, thereby improving the degree of recognition of the first alignment mark MRK1 and the second alignment mark MRK2. The light-shielding film removal area SRA may overlap the first alignment mark MRK1 and the second alignment mark MRK2 in the third direction DR3.

Since the light-shielding film LS is not disposed in the light-shielding film removal area SRA, distortion of the light reflected from the first alignment mark MRK1 and the second alignment mark MRK2 may be hardly generated. Therefore, the degree of recognition of the first alignment mark MRK1 and the second alignment mark MRK2 may be improved during the bonding process of the display device 10, and alignment accuracy between the upper member UM and the display panel 100 may be improved.

Hereinafter, a display device according to an embodiment will be described. In the following embodiment, the same elements as those of the previous embodiment will be denoted by the same reference numerals and their redundant description will be omitted or simplified, and the following description will be based on differences from the previous embodiment.

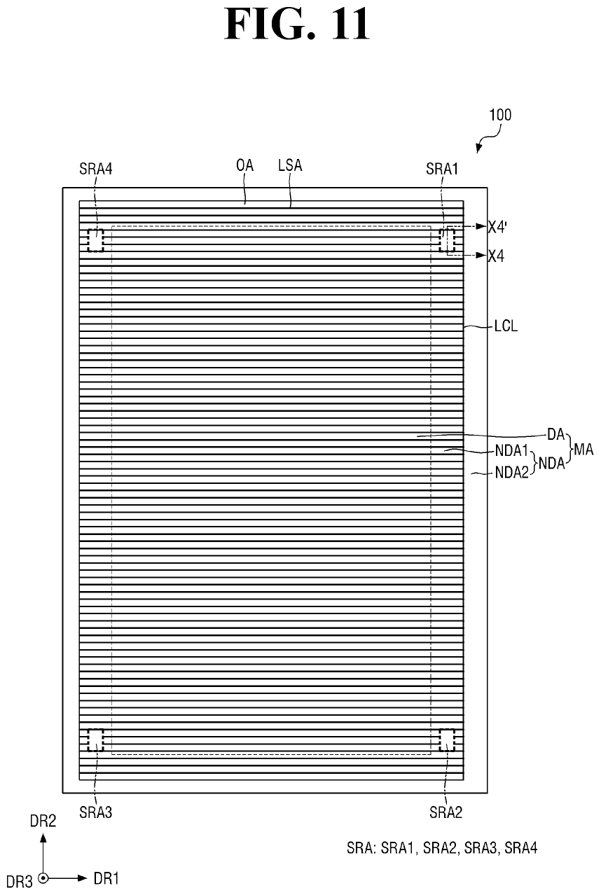

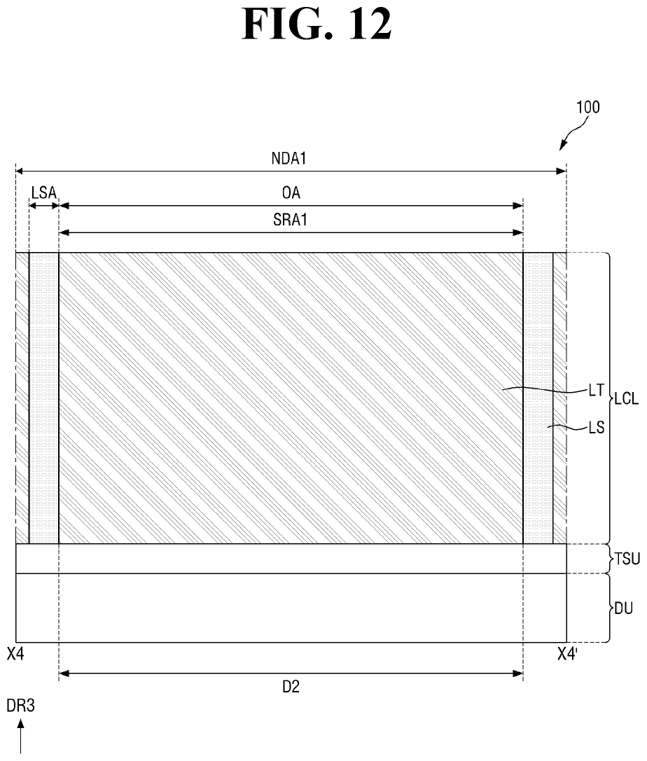

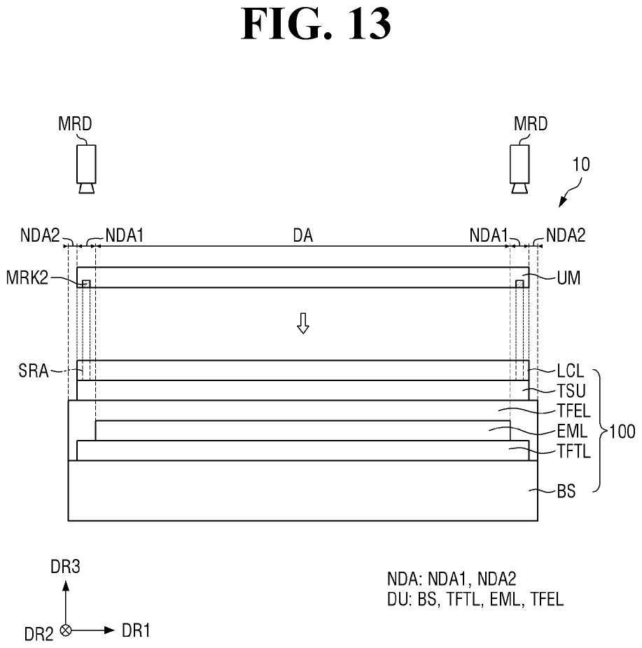

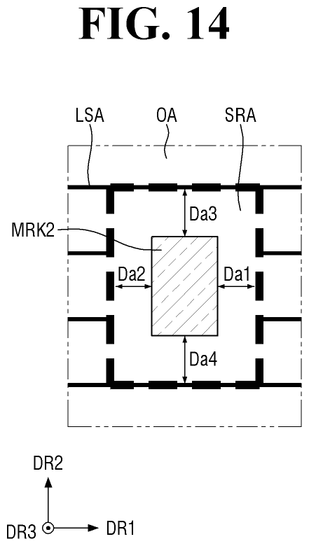

FIG. 11 is a schematic plan view illustrating a display device according to an embodiment. FIG. 12 is a schematic cross-sectional view taken along line X4-X4′ of FIG. 11. FIG. 13 is a schematic cross-sectional view illustrating a bonding process of a display device according to an embodiment. FIG. 14 is a schematic plan view illustrating an aligning process of a second alignment mark and a light-shielding film removal area of a display device according to an embodiment.

Referring to FIGS. 11 to 14, the display device 10 according to an embodiment may be different from the display device 10 according to one embodiment described with reference to FIG. 6 in that the display device 10 does not include the first alignment mark MRK1.

In more detail, the display device 10 according to an embodiment may align the upper member UM and the display panel 100 by directly recognizing the second alignment mark MRK2 of the upper member UM, which is a member to be bonded, and the light-shielding film removal area SRA of the light control layer LCL.

In the display device 10 according to an embodiment, the display panel 100 may not include the first alignment mark MRK1. For example, the first alignment mark MRK1 may not be disposed in the display layer DU and the touch sensor layer TSU of the display panel 100.

Even as shown in FIGS. 13 and 14, the recognition device MRD may directly recognize the second alignment mark MRK2 of the upper member UM and the light-shielding film removal area SRA of the light control layer LCL during the bonding process of the display device 10.

The second alignment mark MRK2 and the light-shielding film removal area SRA may overlap each other in the third direction DR3. In one embodiment, in case that the second alignment mark MRK2 is smaller than the light-shielding film removal area SRA, the recognition device MRD may recognize a distance between each side of the second alignment mark MRK2 and each side of the light-shielding film removal area SRA to check whether the second alignment mark MRK2 and the light-shielding film removal area SRA are aligned.

For example, the recognition device MRD may measure a first distance Da1 that is a distance between a side of the second alignment mark MRK2 and a side of the light-shielding film removal area SRA at a side in the first direction DR1, a second distance Da2 that is a distance between a side of the second alignment mark MRK2 and a side of the light-shielding film removal area SRA at another side in the first direction DR1, a third distance Da3 that is a distance between a side of the second alignment mark MRK2 and a side of the light-shielding film removal area SRA at a side in the second direction DR2, and a fourth distance Da4 that is a distance between a side of the second alignment mark MRK2 and a side of the light-shielding film removal area SRA at another side in the second direction DR2. The recognition device MRD may compare the first to fourth distances Da1, Da2, Da3 and Da4 with stored alignment data to determine whether the second alignment mark MRK2 and the light-shielding film removal area SRA are aligned.

However, the disclosure is not limited to the above example, and in case that the second alignment mark MRK2 and the light-shielding film removal area SRA are the same as each other in sizes and shapes, whether the second alignment mark MRK2 and the light-shielding film removal area SRA are completely matched with each other may be determined to determine whether the second alignment mark MRK2 and the light-shielding film removal area SRA are aligned.

The display device 10 according to an embodiment may check whether each member is aligned by using the second alignment mark MRK2 and the light-shielding film removal area SRA even without the first alignment mark MRK1.

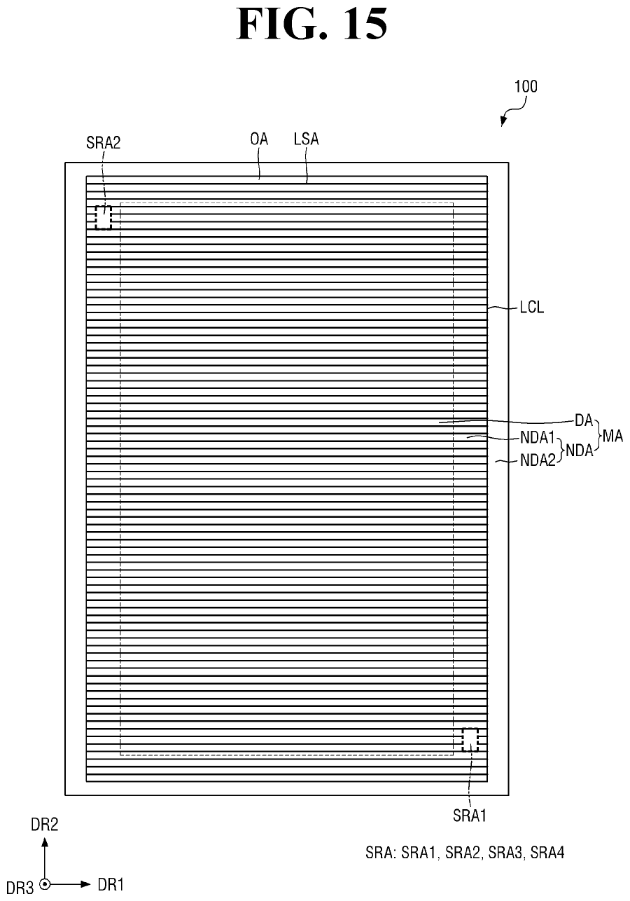

FIGS. 15 to 17 are schematic plan views illustrating a display device according to other embodiments.

Referring to FIGS. 15 to 17, the display device 10 according to embodiments may be different from the display device 10 according to the embodiments described with reference to FIGS. 6 and 11 in the number and position of the light-shielding film removal areas SRA.

In more detail, in the display device 10 according to embodiments, the light-shielding film removal area SRA may include a first light-shielding film removal area SRA1 and a second light-shielding film removal area SRA2.

In case of the display device 10 according to the embodiment of FIG. 15, the light-shielding film removal area SRA may be disposed to be adjacent to each corner of the first non-display area NDA1. For example, the first light-shielding film removal area SRA1 may be disposed at a side in the first direction DR1 and another side in the second direction DR2 among the corners of the first non-display area NDA1, and the second light-shielding film removal area SRA2 may be disposed at another side in the first direction DR1 and a side in the second direction DR2 among the corners of the first non-display area NDA1.

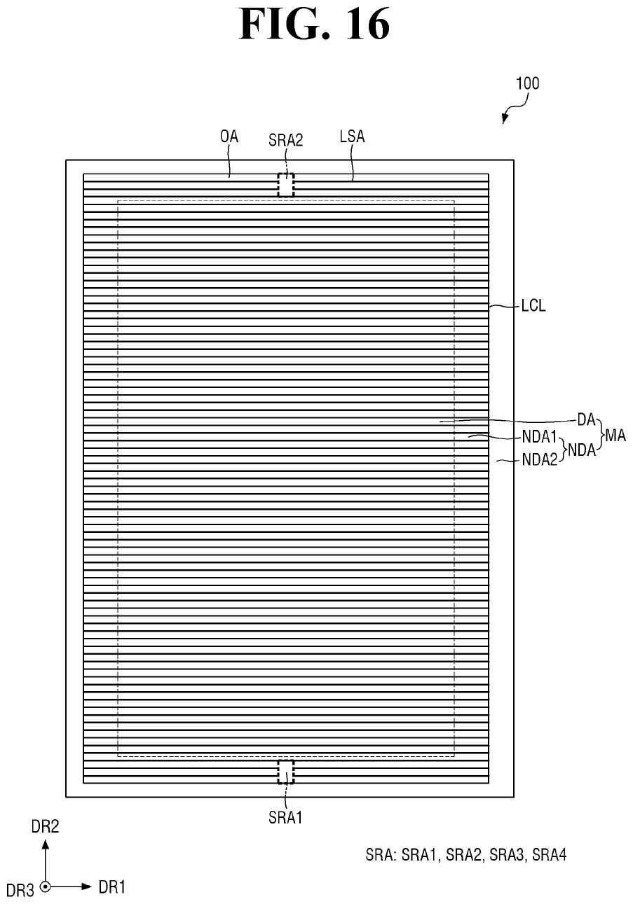

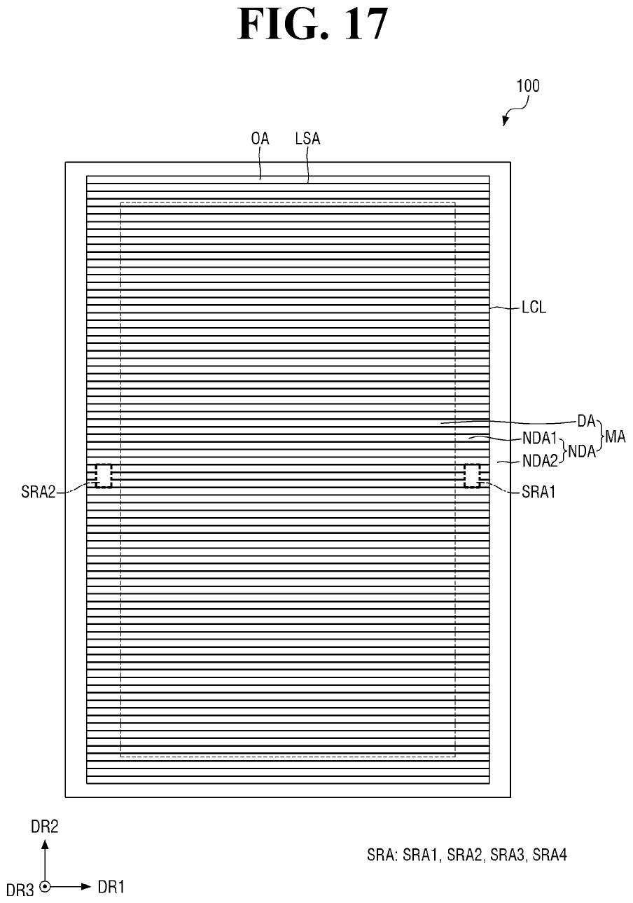

In case of the display device 10 according to the embodiment of FIG. 16 and the embodiment of FIG. 17, the light-shielding film removal area SRA may be disposed to be adjacent to each side of the first non-display area NDA1.

For example, in case of the display device 10 according to the embodiment of FIG. 16, the first light-shielding film removal area SRA1 may be disposed on another side in the second direction DR2 among the sides of the first non-display area NDA1, and the second light-shielding film removal area SRA2 may be disposed on a side in the second direction DR2 among the sides of the first non-display area NDA1. In case of the display device 10 according to the embodiment of FIG. 17, the first light-shielding film removal area SRA1 may be disposed on a side in the first direction DR1 among the sides of the first non-display area NDA1, and the second light-shielding film removal area SRA2 may be disposed on another side in the first direction DR1 among the sides of the first non-display area NDA1.

Although not shown in the drawings, various modifications may be made in the position of the light-shielding film removal area SRA inside of the first non-display area NDA.

In concluding the detailed description, those skilled in the art will appreciate that many variations and modifications can be made to the disclosed embodiments without departing from the principles of the disclosure. Therefore, the disclosed embodiments are used in a generic and descriptive sense only and not for purposes of limitation.

What is claimed is:

1. A display device comprising:
a light emitting element layer disposed on a substrate;
a light control layer disposed on the light emitting element layer, the light control layer including a light-transmitting film and a light-shielding film; and
a first alignment mark disposed between the substrate and the light control layer, wherein
the light-transmitting film and the light-shielding film alternate with each other,
the light control layer includes a light-shielding film removal area in which the light-shielding film is not disposed, and
the light-shielding film removal area overlaps the first alignment mark.

2. The display device of claim 1, wherein the first alignment mark does not overlap the light-shielding film.

3. The display device of claim 1, wherein
the light-shielding film extends in at least a direction in a plan view, and
the light-shielding film is disconnected in the light-shielding film removal area.

4. The display device of claim 1, further comprising:
a display area including a plurality of light emitting elements and a non-display area on a side of the display area, and
wherein the light-shielding film removal area is disposed in the non-display area.

5. The display device of claim 4, wherein the light-shielding film removal area has a light transmittance greater than a light transmittance of a part of the light control layer, the part of the light control layer being disposed in the display area.

6. The display device of claim 4, wherein a width of the light-transmitting film in the light-shielding film removal area is greater than a width of the light-transmitting film in the display area.

7. The display device of claim 4, wherein a size of the light control layer is greater than a size of the display area in a plan view.

8. The display device of claim 1, wherein a size of the light-shielding film removal area is greater than or equal to a size of the first alignment mark.

9. The display device of claim 1, further comprising:
a thin film transistor layer disposed between the substrate and the light emitting element layer,
wherein the first alignment mark is disposed on the thin film transistor layer.

10. The display device of claim 1, further comprising:
a touch sensor layer disposed between the light emitting element layer and the light control layer,
wherein the first alignment mark is disposed on the touch sensor layer.

11. The display device of claim 1, further comprising:
an upper member on the light control layer, the upper member including a second alignment mark,
wherein the second alignment mark overlaps the light-shielding film removal area.

12. The display device of claim 11, wherein the first alignment mark overlaps the second alignment mark.

13. A display device comprising:
a light emitting element layer disposed on a substrate;
a light control layer disposed on the light emitting element layer, the light control layer including a light-transmitting film and a light-shielding film; and
an upper member disposed on the light control layer, the upper member including a first alignment mark, wherein
the light-transmitting film and the light-shielding film alternate with each other,
the light control layer includes a light-shielding film removal area in which the light-shielding film is not disposed, and
the light-shielding film removal area overlaps the first alignment mark.

14. The display device of claim 13, wherein the first alignment mark does not overlap the light-shielding film.

15. The display device of claim 13, wherein
the light-shielding film extends in at least a direction in a plan view, and
the light-shielding film is disconnected in the light-shielding film removal area.

16. The display device of claim 13, wherein a size of the light-shielding film removal area is greater than or equal to a size of the first alignment mark.

17. A display device comprising:
a display area and a non-display area on a side of the display area;
a light emitting element layer disposed on a substrate; and
a light control layer disposed on the light emitting element layer, the light control layer including a light-transmitting film and a light-shielding film, wherein
the light control layer includes:
a plurality of transmissive areas in which the light-shielding film is not disposed;
a plurality of non-transmissive areas in which the light-shielding film is disposed and which alternate with the plurality of transmissive areas; and
a first area in which the light-shielding film is not disposed in the non-display area, and
a width of the first area is greater than a width of one of the plurality of transmissive areas.

18. The display device of claim 17, further comprising:
an alignment mark on the non-display area,
wherein the first area overlaps the alignment mark.

19. The display device of claim 18, wherein a size of the first area is greater than or equal to a size of the alignment mark.

20. The display device of claim 17, wherein a size of the light control layer is greater than a size of the display area in a plan view.
